(19) United States
(12) Patent Application Publication
(10) Pub. No.: US 2016/0153923 A1
(43) Pub. Date: Jun. 2, 2016

(54) METHOD FOR EXTRACTING TRAP TIME CONSTANT OF GATE DIELECTRIC LAYER IN SEMICONDUCTOR DEVICE

(71) Applicant: PEKING UNIVERSITY, Beijing (CN)

(72) Inventors: Ru HUANG, Beijing (CN); Shaofeng GUO, Beijing (CN); Runsheng WANG, Beijing (CN); Pengpeng REN, Beijing (CN); Xiaobo JIANG, Beijing (CN); Mulong LUO, Beijing (CN); Xing ZHANG, Beijing (CN)

(21) Appl. No.: 14/784,881

(22) PCT Filed: Jan. 8, 2014
(86) PCT No.: PCT/CN2014/070314

§ 371 Date: Oct. 15, 2015

(30) Foreign Application Priority Data
Aug. 21, 2013 (CN) 201310367172.8

(51) Int. Cl. G01N 27/02; G01R 31/26

(52) U.S. Cl. CPC G01N 27/02; G01R 31/2601

(57) ABSTRACT

The present invention discloses a method for extracting a trap time constant of a gate dielectric layer in a semiconductor device, which is related to the reliability of microelectronic devices. The method comprises initializing a state of a trap in the semiconductor device so that the trap finally comes to an empty state; applying a DC or

AC signal to a gate terminal and a zero bias Vd1 to a drain terminal; after a period of time t1, applying small voltages Vg2 and Vd2 to the gate and drain terminals respectively, and detecting a state of a drain current Id; modifying the time t1 to t2=t1+Δt while maintaining other conditions; repeatedly performing the previous steps in a same manner to perform N times of measurements for N numbers of time points t1, t1+Δt, . . . , t1+(N−1)Δt so as to obtain the respective states of the drain current correspond thereto; conducting moving average and calculating respective occupation probabilities P corresponding to the (N-n) numbers of time points; fitting by using an equation to obtain a trap capture time constant and a trap emission time constant.

### CROSS-REFERENCES TO RELATED APPLICATION

This application is the United States National Stage of and claims priority to International Application No. PCT/CN2014/070314, which was filed on Jan. 8, 2014, that claims the priority of Chinese Patent Application No. 201310367172.8, which was filed on Aug. 21, 2013, the disclosures which are incorporated herein by reference in their entirety.

### TECHNICAL FIELD

The present invention relates to the reliability of microelectronic devices, and relates to a method for extracting a trap time constant of a gate dielectric layer in a small-size semiconductor device.

### BACKGROUND OF THE INVENTION

As the size of semiconductor devices continues to shrink, the number of traps in the gate dielectric layer gradually reduce, which brings an increasing attention to the random behavior of the traps. Furthermore, the influences in the electrical properties caused by a single trap in small-size devices are much larger than that in large-size devices. This will cause a serious impact on circuits, such as an increased delay in some logic circuits and a failure reading in the static random access memory (SRAM). Therefore, studying the trap behavior in the small-size devices and fully understanding the basic characteristics of the traps are important in predicting the deterioration characteristics of the circuits as well as in the reliability design of the circuits.

There are primarily three aspects for describing the trap characteristics: a trap capture (electrons or holes) time constant, a trap emission (electrons or holes) time constant, and a degradation amplitude in the electrical properties caused by traps (hereinafter referred to as the trap amplitude). The capture time for the trap from an empty state to an occupied state each time and the emission time for the trap from an occupied state to an empty state are random, which comply to an exponential distribution. The mean values of the emission time and of the capture time are the emission time constant and the capture time constant. When a gate voltage is high, the capture time constant is large and the emission time constant is small; when the gate voltage is low, the emission time constant is small and the capture time constant is large. In the case of not considering the changes of the applied voltage and other factors such as the trap coupling, the amplitude caused by the trap is substantially constant, so it is easy to distinguish the role of different traps in the testing.

Since the emission and capture of traps have a random and unpredictable nature, the trap behavior is usually characterized by a statistical occupation probability (or emission probability). As time increases, the occupation probability of a trap that has an initial empty state is increased exponentially; the emission probability of a trap that has an initial occupied state is also increased exponentially. Usually, the trap time constant may be extracted by directly detecting the state of the drain current at a certain gate voltage and then respectively averaging the time length at two current states. As a result, the corresponding two time constants can be obtained. At the certain gate voltage, there may be a case that the two time constant have a large order of magnitude difference, Thus, the above method is limited by the testing time and the storage amount of the test instrument and thus is difficult to implement. However, this is also an important research category. To this end, the testing for the trap time constant is needed to be carried out by other effective methods. In particular, the problems mentioned above are needed to be solved so as to support the study of the trap behavior. In this regard, conventionally, the occupation probabilities of a plurality of time points are obtained by testing, and then the time constants are obtained by fitting in accordance with a model in the method. However, such a method has low efficiency and requires a large numbers of testing data to meet a certain accuracy. Therefore, it is necessary to propose a highly efficient and accuracy-satisfactory method for testing and extracting the trap time constant.

### SUMMARY OF THE INVENTION

The present invention is to provide a method for extracting a trap time constant of a gate dielectric layer in a semiconductor device. The method is highly efficient and ensures sufficient accuracy.

The technical solutions of the present invention are described as follows (a case that a trap has an initial empty state and a capture time constant is extracted is illustrated. Throughout the testing process, Vg for a source terminal and Vb for a body terminal are grounded, that is, zero-biased all the time).

Firstly, the state of the trap in the semiconductor device is initialized. A gate terminal and a drain terminal are grounded, that is, zero-biased. A sufficiently long period of time is maintained so that the trap finally comes to the empty state.

In the 2^{nd} step, a voltage signal Vg1 is applied to the gate terminal and a zero bias Vd1 is applied to the drain terminal. After a period of time t1, small voltages Vg2 and Vd2 are applied to the gate and drain terminals, respectively, and a state of a drain current (Id) is detected. Since an emission may be easily occurred in the trap at the low voltage level, if an obvious hopping is observed, it means a capture behavior of the trap occurs in the period of time t1, and thus 1 is recorded; if the hopping of the current state is not observed, then 0 is recorded.

In the 3^{rd} step, based on the method of the 2^{nd} step, the time t1 is modified to t2=t1+Δt while maintaining the other conditions, and the state of the drain current is detected by recording 1 or 0. Then, the testing is repeatedly performed with the other conditions unchanged, except that the time for applying the stress is increased by Δt all the way. As such, N times of measurements are performed to obtain the respective states (1 or 0) corresponding to N numbers of time points t1, t1+Δt, . . . , t1+(N−1)Δt.

In the 4^{th} step, the N numbers of 1/0 values are moving-averaged in a time order. For example, a sum of the 1^{th} value 1/0 to the n^{th} value 1/0 is divided by n to obtain an average occupation probability, which is used as an occupation probability of a central time point among the n numbers of time points. Then, a sum of the 2^{nd} value 1/0 to the (n+1)^{th} value 1/0 is divided by n to obtain an occupation probability of a central time point among the n numbers of time points. Calculation is performed in the same manner as forgoing. As a result, the occupation probabilities corresponding to the (N-n) numbers of time points are obtained.

In the 5^{th} step, the occupation probability of a single trap varying with time is represented as follows:

$$DC case P = \frac{{τ}_{e}}{{τ}_{e} + {τ}_{c}} ( 1 - exp ( - \frac{{τ}_{e} + {τ}_{c}}{{τ}_{c} {τ}_{e}} t ) ) \qquad ( 1 )$$

In the above equation, P is the occupation probability corresponding to each time point obtained in the 4^{th} step; t is the time for applying the signal in the 2^{nd} and 3^{rd} steps; τ_{c} and τₑ correspond to a trap capture time constant and a trap emission time constant under DC, respectively. Fitting is performed to obtain τ_{c} and τₑ by using the occupation probabilities P obtained through the previous testing and the corresponding time points. In this case, the τ_{c} value obtained by fitting has high accuracy, but the τₑ value obtained by fitting serves as a reference value (if the accuracy of τₑ is to be tested, in a similar way, the signal may be set oppositely).

Similarly, for the AC case, the method is performed in a same way except for the followings.

(1) The signal applied to the gate terminal in the 2^{nd} and 3^{rd} steps is an AC signal. Integer numbers of complete signal cycles are included in the time for applying the AC signal. The setting for the signal in the initialization of the state and the recovery and detection of the state are exactly the same as the DC case.

(2) For the AC case, the occupation probability varying with time is represented as follows:

$$AC case ( duty cycle DF = 0.5 ) \\ P = \frac{{τ}_{eL}}{{τ}_{eL} + {τ}_{cH}} ( 1 - exp ( - \frac{{τ}_{eL} + {τ}_{cH}}{2 {τ}_{cH} {τ}_{eL}} t ) ) \qquad ( 2 )$$

In the above equation, P is the occupation probability corresponding to each time point obtained in the 4^{th} step; t is the time for applying the signal in the 2^{nd} and 3^{rd} steps; τ_{cH} and τ_{eL} correspond to the trap capture time constant at the high voltage level and the trap emission time constant at the low voltage level under AC, respectively. Since the emission time constant τ_{eH} at the high voltage level is much larger than the emission time constant τ_{eL} at the low voltage level, and the capture time constant τ_{cL} at the low voltage level is much larger than the capture time constant τ_{cH} at the high voltage level, the influences by τ_{eH} and τ_{cL} can be omitted.

Then, the results of the testing are fitted by using the equation corresponding to the AC case. As a result, a relatively high accurate capture time constant at the high voltage level under AC can be obtained. Meanwhile, the obtained emission time constant at the low voltage level may be used as a reference (the testing and extracting process for the emission time constant at the low voltage level under AC may be performed in an exactly same way as the process mentioned above).

According to the present invention, the testing method can have less testing data points and thus contributes to the efficiency of the testing. Furthermore, the way that the data points are processed through the moving averaging method to obtain the occupation probabilities of the corresponding time points can ensure that the time constant obtained by the extracting satisfies the required accuracy for studying. In particular, for the cases that the two time constants of the trap differ by a large order of magnitude, the testing method has no difficulties and the testing instrument is easy to meet the requirement. Therefore, the present method provides a convenient and an efficient way to study the effects of different factors on the basic parameters of the trap.

### BRIEF DESCRIPTION OF THE DRAWINGS

FIG. 1 shows a schematic view of a four-terminal semiconductor device.

FIG. 2 shows a schematic diagram of the timing signals applied to the gate and drain terminals during testing the trap capture time constant of the gate dielectric layer under DC, where (a) shows the timing signal applied to the gate terminal during testing the trap capture time constant of the gate dielectric layer under DC; (b) shows the timing signal applied to the drain terminal during testing the trap capture time constant of the gate dielectric layer under DC.

FIG. 3 shows a schematic diagram of the testing signal pulses applied to the gate and drain terminals during testing the trap capture time constant of the gate dielectric layer under AC, where (a) shows the testing signal pulse applied to the gate terminal during testing the trap capture time constant of the gate dielectric layer under AC; (b) shows the testing signal pulse applied to the drain terminal during testing the trap capture time constant of the gate dielectric layer under AC.

FIG. 4 shows a schematic diagram of the timing signals applied to the gate and drain terminals during testing the trap emission time constant of the gate dielectric layer under DC, where (a) shows the timing signal applied to the gate terminal during testing the trap emission time constant of the gate dielectric layer under DC; (b) shows the timing signal applied to the drain terminal during testing the trap emission time constant of the gate dielectric layer under DC.

FIG. 5 shows a schematic diagram of the testing signal pulses applied to the gate and drain terminals during testing the trap emission time constant of the gate dielectric layer under AC, where (a) shows the testing signal pulse applied to the gate terminal during testing the trap emission time constant of the gate dielectric layer under AC; (b) shows the testing signal pulse applied to the drain terminal during testing the trap emission time constant of the gate dielectric layer under AC.

FIG. 6 shows a schematic diagram of the drain current in detecting its state so as to determine whether the capture behavior occurs in the trap, where (a) shows the signal bias for the drain terminal, which is divided into two phases; (b) shows a state of the drain current during the testing phase, indicating a case that the pulse applied to the gate terminal causes the capture behavior to occur in the trap, because an obvious hopping is existed; (c) shows a state of the drain current during the testing phase, indicating a case that the pulse applied to the gate terminal does not cause the capture behavior to occur in the trap.

FIG. 7 shows a schematic diagram of the drain current in detecting its state so as to determine whether the emission behavior occurs in the trap, where (a) shows the signal bias for the drain terminal, which is divided into two phases; (b) shows a state of the drain current during the testing phase, indicating a case that the pulse applied to the gate terminal causes the emission behavior to occur in the trap, because an obvious hopping is existed; (c) shows a state of the drain current during the testing phase, indicating a case that the pulse applied to the gate terminal does not cause the emission behavior to occur in the trap.

FIG. 8 shows a schematic diagram of the original data points as the testing results, where (a) shows a schematic diagram of N numbers of 0/1 data points; (b) shows a partial enlarged diagram.

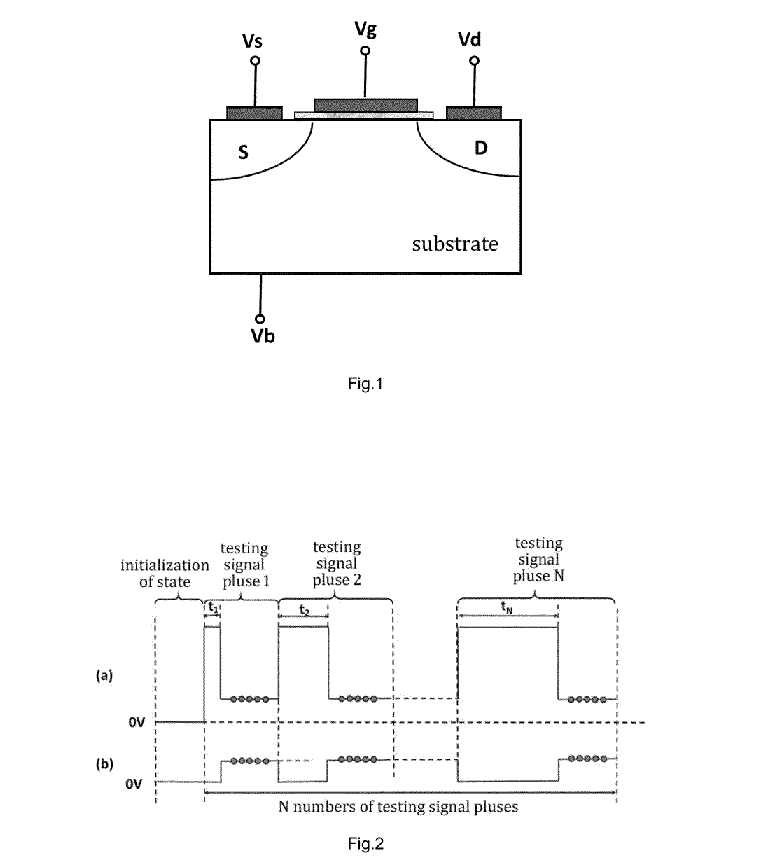

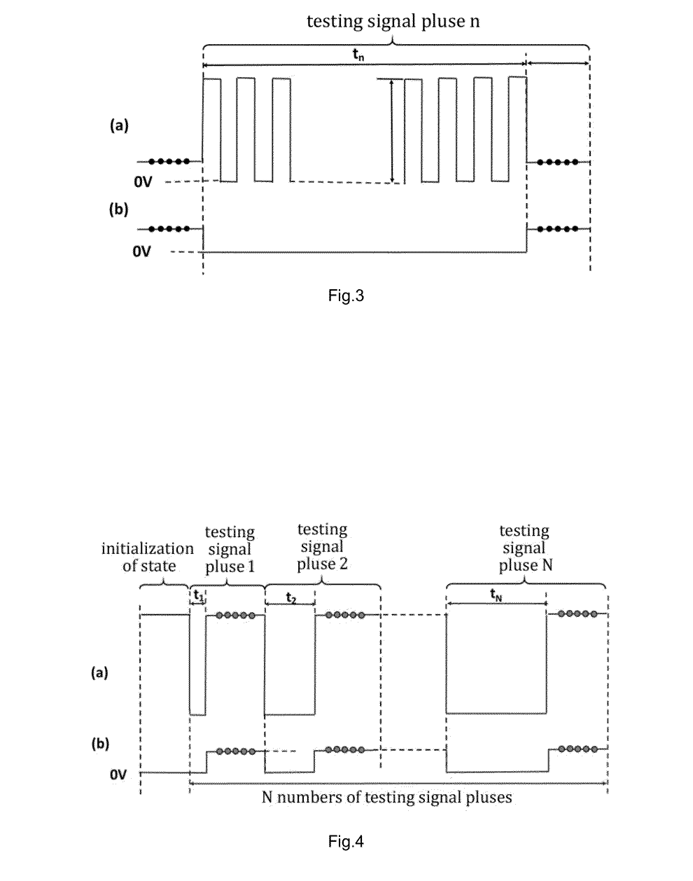

### DETAILED DESCRIPTION OF THE EMBODIMENTS

Hereinafter, the testing method of the present invention will be described in detail by the embodiments in view of the accompanying drawings.

The testing steps and the data processing method are illustrated as follows.

THE TESTING (the testing steps described below are directed to the testing and extracting of the capture time constant under DC for an N-type device, during which both of the source and body terminals are grounded, that is, zero-biased, and probes A and B are connected to the gate and drain terminals, respectively)

1) In this step, the state of the trap is initialized to ensure that, before applying a high voltage level signal, the trap is in an empty state. To this end, the drain terminal is connected to a voltage Vd0, and the gate terminal is connected to a voltage Vg0. Herein, Vd0 and Vg0 are the ground signal, that is, a zero bias is applied. In other words, it is to be ensured that the device is free of any applied stress for a sufficient period of time. Since the trap emission time constant at the low voltage level is very small, the object of this step may be easily attained.

2) In this testing step, a pulse level condition to be studied is applied to the gate terminal. In this regard, a voltage bias signal Vg1 is started to be applied to the gate terminal after the initialization, where the signal applied to the gate terminal is as shown in the first part of the testing signal pulse 1 in the FIG. 2(a), the high voltage level lasting for a period of time t1 in total. Meanwhile, during applying the high level bias signal to the gate terminal, the drain terminal is zero-biased, as shown in FIG. 2(b).

3) In this testing step, the bias condition applied to the gate terminal is removed, and it is to observe, through a recovery process, whether a hopping exists in the drain current Id. If the hopping exists, it means that the capture behavior occurred in the trap during the high level phase; if no hopping exists, it means that no hopping or more than one hoppings occurred in the trap during the prior high level phase. In short, it is needed to record the state of the trap for the time t1. This process usually lasts a relatively long time to enable the trap to be released in the case that the capture behavior occurred during the high level phase. The specific operation process is illustrated as follows. The voltage signals applied to the gate and drain terminals by the probes A and B are changed to signals Vg2 and Vd2 that are set for the recovery and detection after the time t1. Meanwhile, the probe B may detect an amplitude of the drain current Id in a sampling rate of 106-108/s. During the current detection, if a current hopping is observed, a record may be made that the trap was in an occupied state at t0, which is represented by ‘1’; if no hopping is observed, a record may be made that the trap was in an unoccupied state at t0, which is represented by ‘0’.

4) The steps 2) and 3) are repeatedly performed through the probes A and B, except for the difference that the time for applying the voltage signal to the gate terminal by the probe A is changed from t1 to t2, where t2=t1+Δt, and meanwhile the time for applying the voltage signal to the drain terminal by the probe B is changed accordingly, as shown in FIG. 2. Accordingly, the recorded result corresponds to the states ‘1’ and ‘0’ of the time t2. Then, the testing is repeatedly performed in such a manner that each time only Δt for the time is increased, while other conditions remain unchanged. As such, after the N times of repeating, N numbers of binary data ‘0’ and ‘1’ are recorded, as shown in FIG. 8.

### The Data Processing Method

5) After the testing, N numbers of 0/1 arranged in a time progressive order are obtained. Then, the N numbers of binary data are moving-averaged. An example of the specific algorithm is described as follows. The 1^{th} to (n−1)^{th} data are summed and divided by n to obtain an average occupation probability for a time interval corresponding to the n numbers of data. The average occupation probability is then used as an occupation probability of a central point among the n numbers of time points. Subsequently, the 2^{rd} to (n+1)^{th} points are conducted with the same calculation as the foregoing. The resultant data is then used as an occupation probability of a central point in a time interval corresponding to the 2^{rd} to (n+1)^{th} data. Calculation is conducted in a same manner as the foregoing. As a result, occupation probabilities corresponding to the (N-n) numbers of data points can be obtained.

6) Under DC, the occupation probability of the trap varying with time is as shown in equation (1). The data of the respective occupation probabilities corresponding to the (N-n) numbers of time points obtained according to step 5) are fitted by using the equation (1). As a result, the capture time constant τ_{c} and the emission time constant τₑ can be obtained, where the former has a high accuracy and can meet the testing purpose.

The above descriptions are directed to the complete steps for testing and extracting the trap capture time constant of the gate dielectric layer under DC. For the AC case, the capture time constant at the high voltage level may be tested and extracted by adopting a similar method, expect that the DC signal is changed to an AC signal during applying the voltage signal by the probe A to the gate terminal. The other signal process remains the same. Furthermore, in the final data fitting process, a model of the occupation probability under AC is represented by equation (2) instead of the equation (1). As a result, an accurate capture time constant at the high voltage level may be obtained.

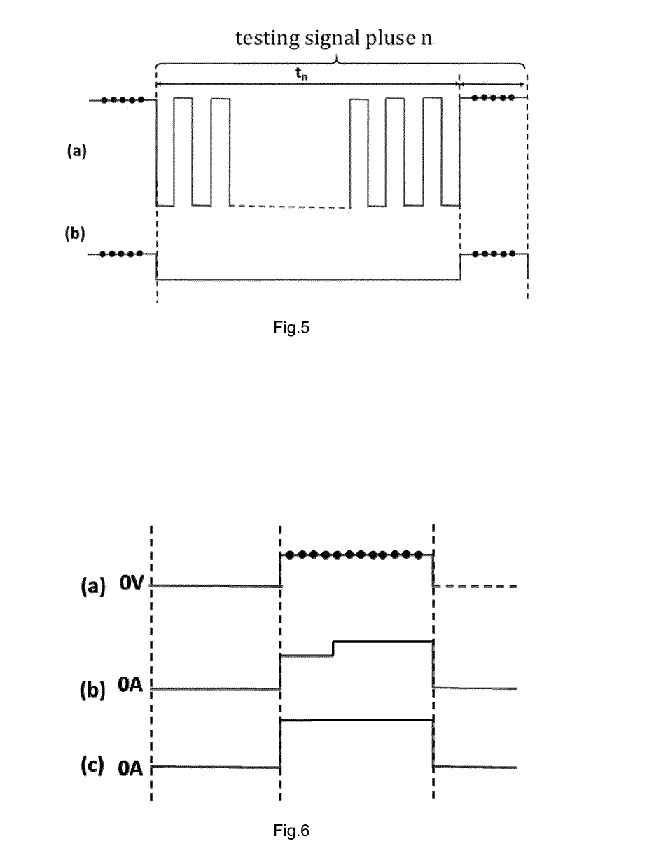

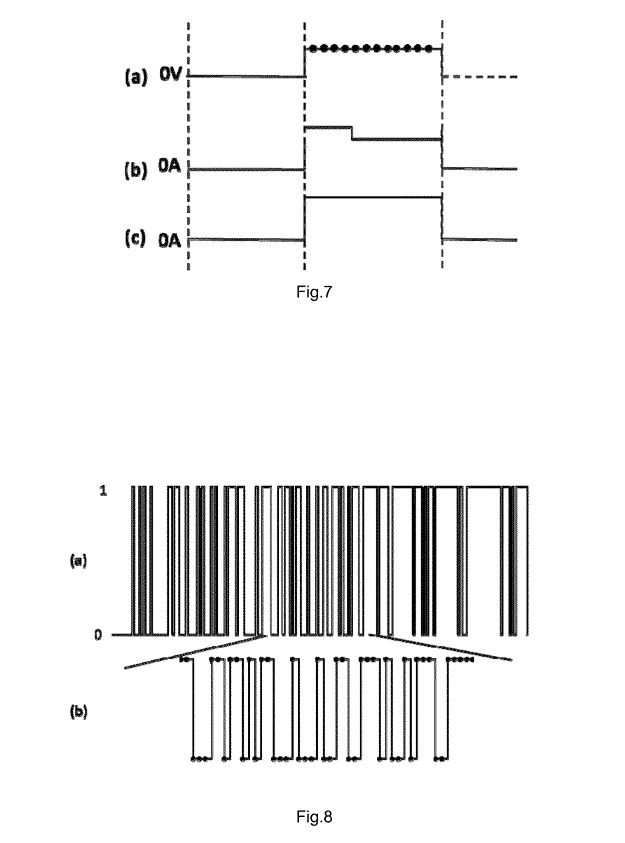

The method described above is directed to the testing and extracting of the capture time constant. However, the method is also suitable for the testing and extracting of the emission time constant. In this case, the timing signals of DC/AC voltage applied to the gate and drain terminals are as shown in FIG. 4 and FIG. 5, and the data processing and fitting are as same as the foregoing case.

The embodiments described above are not intended to limit the present invention. Various changes and modifications may be made by those skilled in the art without departing from the spirit and scope of the present invention, and therefore the protection scope of the present invention is defined by the claims.

What is claimed is:

1. A method for extracting a trap time constant of a gate dielectric layer in a semiconductor device, comprising the following steps:
A. initializing a state of a trap in the semiconductor device so that the trap finally comes to an empty state;
B. applying a DC signal Vg1 to a gate terminal and a zero bias Vd1 to a drain terminal; after a period of time t1, applying small voltages Vg2 and Vd2 to the gate and drain terminals respectively, and detecting a state of a drain current Id;
C. based on the method in the step B, modifying the time t1 to t2=t1+Δt while maintaining other conditions, and detecting the state of the drain current; performing N times of measurements for N numbers of time points t1, t1+Δt, . . . , t1+(N−1)Δt so as to obtain the respective states of the drain current correspond thereto;
D. obtaining N numbers of records 0/1 according to whether a hopping occurs in the state of the drain current; moving-averaging the N numbers of records 0/1 in a time order by a step of n, and calculating respective occupation probabilities P corresponding to the (N-n) numbers of time points;
E. fitting by using an equation to obtain
$$P = \frac{{τ}_{e}}{{τ}_{e} + {τ}_{c}} ( 1 - exp ( - \frac{{τ}_{e} + {τ}_{c}}{{τ}_{c} {τ}_{e}} t ) )$$
to obtain τ_{c} and τₑ, where τ_{c} and τₑ correspond to a trap capture time constant and a trap emission time constant under the DC signal, respectively.

2. The method according to claim 1, wherein the moving-averaging in the step D comprises dividing a sum of the 1^{th} value 0/1 to the n^{th} value 0/1 by n to obtain an average occupation probability, which is used as an occupation probability of a central time point among the n numbers of time points; dividing a sum of the 2^{rd} value 0/1 to the (n+1)^{th} value 0/1 by n to obtain an occupation probability of a central time point among the n numbers of time points; calculating in the same manner as the foregoing.

3. A method for extracting a trap time constant of a gate dielectric layer in a semiconductor device, comprising the following steps:
F. initializing a state of a trap in the semiconductor device so that the trap finally comes to an empty state;
G. applying an AC signal to a gate terminal and a zero bias Vd1 to a drain terminal;
after a period of time t1, applying small voltages Vg2 and Vd2 to the gate and drain terminals respectively, and detecting a state of a drain current Id;
H. based on the method in the step G, modifying the time t1 to t2=t1+Δt while maintaining other conditions, and detecting the state of the drain current; performing N times of measurements for N numbers of time points t1, t1+Δt, . . . , t1+(N−1)Δt so as to obtain the respective states of the drain current correspond thereto;
I. obtaining N numbers of records 0/1 according to whether a hopping occurs in the state of the drain current; moving-averaging the N numbers of records 0/1 in a time order by a step of n, and calculating respective occupation probabilities P corresponding to the (N-n) numbers of time points;
J. fitting by using an equation
$$P = \frac{{τ}_{eL}}{{τ}_{eL} + {τ}_{cH}} ( 1 - exp ( - \frac{{τ}_{eL} + {τ}_{cH}}{2 {τ}_{cH} {τ}_{eL}} t ) )$$
to obtain τ_{cH} and τ_{eL}, where τ_{cH} and τ_{eL} correspond to a trap capture time constant at a high voltage level and a trap emission time constant at a low voltage level under the AC signal, respectively.

4. The method according to claim 3, wherein the moving-averaging in the step I comprises dividing a sum of the 1^{th} value 0/1 to the n^{th} value 0/1 by n to obtain an average occupation probability, which is used as an occupation probability of a central time point among the n numbers of time points; dividing a sum of the 2^{rd} value 0/1 to the (n+1)^{th} value 0/1 by n to obtain an occupation probability of a central time point among the n numbers of time points; calculating in the same manner as the foregoing.
